(19) United States
(12) Patent Application Publication
(10) Pub. No.: US 2007/0059502 A1
(43) Pub. Date: Mar. 15, 2007

(54) Integrated process for sputter deposition of a conductive barrier layer, especially an alloy of ruthenium and tantalum, underlying copper or copper alloy seed layer

(75) Inventors: Rongjun Wang, Cupertino, CA (US); Hua Chung, San Jose, CA (US); Xianmin Tang, San Jose, CA (US); Jenn Yue Wang, Fremont, CA (US); Wei D. Wang, San Jose, CA (US); Yoichiro Tanaka, Santa Clara, CA (US); Jick M. Yu, San Jose, CA (US); Praburam Gopalraja, San Jose, CA (US)

Correspondence Address: LAW OFFICES OF CHARLES GUENZER;ATTN: APPLIED MATERIALS, INC., 2211 PARK BOULEVARD, P.O. BOX 60729, PALO ALTO, CA, 94306, US

(73) Assignee: Applied Materials, Inc., Santa Clara, CA (US)

(21) Appl. No.: 11/511,869

(22) Filed: Aug. 29, 2006

Related U.S. Application Data
(63) Continuation-in-part of application No. 11/124,611, filed on May 5, 2005.

(51) Int. Cl. B32B 7/00; B32B 3/00; C23C 16/00; B05D 5/12; C23C 14/00

(52) U.S. Cl. 428/209; 428/210; 427/97.7; 427/248.1; 204/192.15

(57) ABSTRACT

A fabrication method and a product for the deposition of a conductive barrier or other liner layer in a vertical electrical interconnect structure. One embodiment includes within a a hole through a dielectric layer a barrier layer of RuTaN, an adhesion layer of RuTa, and a copper seed layer forming a liner for electroplating of copper. The ruthenium content is preferably greater than 50 at % and more preferably at least 80 at % but less than 95 at %. The barrier and adhesion layers may both be sputter deposited. Other platinum-group elements substitute for the ruthenium and other refractory metals substitute for the tantalum. Aluminum alloying into RuTa when annealed presents a moisture barrier. Copper contacts include different alloying fractions of RuTa to shift the work function to the doping type.

### RELATED APPLICATION

This application is a continuation in part of Ser. No. 11/124,611, filed May 5, 2005.

### FIELD OF THE INVENTION

The invention relates generally to electrical interconnects including a barrier layer in semiconductor integrated circuits. In particular the invention relates to conductive metal barriers that are not subject to oxidation, such as amorphous metal barriers, or are conductive when oxidized and their sputter deposition.

### BACKGROUND ART

Sputtering, alternatively called physical vapor deposition (PVD), is the most prevalent method of depositing layers of metals and related materials in the fabrication of silicon integrated circuits. One challenging application in the fabrication of advanced integrated circuits is the sputter deposition of thin liner layers in vertical electrical interconnects, usually called vias, for copper metallization. A conventional magnetron sputter reactor 10, illustrated schematically in cross section in FIG. 1, with different targets can effectively sputter thin films of Cu, Ta, TaN, and other materials into holes having high aspect ratios and can further act to plasma clean the substrate. The reactor 10 includes a vacuum chamber 12 arranged generally symmetrically about a central axis 14. A vacuum pump system 16 pumps the chamber 12 to a very low base pressure in the range of 10⁻⁶ Torr. However, a gas source 18 connected to the chamber through a mass flow controller 20 supplies argon as a sputter working gas. The argon pressure inside the chamber 12 is typically held in the low milliTorr range. A second gas source 22 supplies nitrogen gas into the chamber through a second mass flow controller 24 when a metal nitride is being deposited.

A pedestal 30 arranged about the central axis 14 holds a wafer 32 or other substrate to be sputter coated. An unillustrated clamp ring or electrostatic chuck may be used to hold the wafer 32 to the pedestal 30. An RF power supply 34 is connected through a capacitive coupling circuit 36 to the pedestal 30, which is conductive and acts as an electrode. In the presence of a plasma, the capacitively RF-biased pedestal 30 develops a negative DC self-bias, which effectively attracts and accelerates positive ions in the plasma. An electrically grounded shield 36 protects the chamber walls and the sides of the pedestal 30 from sputter deposition. A target 38 of the chosen deposition material is arranged in opposition to the pedestal 30 and is vacuum sealed to but electrically isolated from the chamber 12 through an isolator 40. At least the front surface of the target 38 is composed of a metallic material to be deposited on the wafer 32, which for the conventional liner materials is either copper or tantalum.

A DC power supply 42 electrically biases the target 38 negatively with respect to the grounded shield 36 to cause the argon to discharge into a plasma such that the positively charged argon ions are attracted to the negatively biased target 38 and sputter target material from it. Some of the sputtered atoms fall upon the wafer 32 and deposit as a layer of the target material on it. In reactive sputtering of tantalum or other metal, reactive nitrogen gas is additionally flowed into the chamber 12 from the nitrogen source 18 to react with the tantalum being sputtered to cause the deposition of a tantalum nitride layer on the wafer 32.

The target sputtering rate and sputter ionization fraction can be greatly increased by placing a magnetron 44 in back of the target 38. The magnetron 44 is preferably small, strong, and unbalanced. The smallness and strength increase the magnetic field density and hence ionization ratio and the imbalance projects a magnet field into the processing region for at least two effects of guiding sputtered ions to the wafer and reducing plasma loss to the walls. Such a magnetron includes an inner pole 46 of one magnetic polarity along the central axis 14 and an outer pole 48 which surrounds the inner pole 48 and has the opposite magnetic polarity. The magnetic field extending between the poles 46, 48 in front of the target 38 creates a high-density plasma region 50 adjacent the front face of the target 46, which greatly increases the sputtering rate. The magnetron 44 is unbalanced in the sense that the total magnetic intensity of the outer pole 48, that is, the magnetic flux integrated over its area, is substantially greater than that of the inner pole, for example, by a factor of two or more. The unbalanced magnetic field projects from the target 38 toward the wafer 32 to extend the plasma and to guide sputtered ions to the wafer 32 and reduce plasma diffusion to the sides. The magnetron 44 may be formed in a round, triangular, or arc shape that is asymmetrical about the central axis 14 and in different applications extends substantially from the central axis 14 to the outer limit of the useful area of the target 38 or is concentrated in the peripheral area of the target 38. A motor 52 drives a rotary shaft 54, which extends along the central axis 14 and is fixed to a plate 56 supporting the magnetic poles 46, 48 to rotate the magnetron 44 about the central axis 14 and produce an azimuthally uniform time-averaged magnetic field. If the magnetic poles 46, 48 are formed by respective arrays of opposed cylindrical permanent magnets, the plate 56 is advantageously formed of a magnetic material such as magnetically soft stainless steel to serve as a magnetic yoke.

Additional elements may be added to increase the performance. An auxiliary RF inductive coil 70 is powered by an RF power supply 72 and a coil array 74 of electromagnet coils, for example, four annular coils in a rectangular array, each of which may be independently powered by a DC power supply system 76. The coil array 74 is lower in the chamber than disclosed previously and may be at least partially located axially in back of the wafer 32. Electrically floating shields and sidewall magnets may also be added. Other shield configurations are possible.

A conventional copper/tantalum liner via structure 80 is illustrated in the cross-sectional view of FIG. 2. A conductive feature 82 is formed in a lower-level dielectric layer 84. For a copper inter-level interconnect, the conductive feature 82 may be a copper layer embedded in the lower-level dielectric layer 84. An upper-level dielectric layer 86 is deposited over both the conductive feature 82 and the remaining exposed upper surface of the lower-level dielectric layer 84. Silicon dioxide is the conventional dielectric material of both dielectric layers 84, 86 but other low-k materials are being developed, but at the present time they are most usually oxide materials, often porous oxysilicon carbide with significant hydrogen content. A via hole 88 is etched through the upper-level dielectric layer 86 to overlie and expose the conductive feature 82. The via hole 88 will serve as a vertical electrical connection between the conductive feature 82 and other conductive features and horizontal interconnects formed in and above the upper-level dielectric layer.

Copper is the currently preferred material for the various electrical connections in advanced integrated circuits. However, copper cannot directly contact the dielectric layer 86. Copper does not adhere well to oxide. Copper also can diffuse into the upper-level dielectric layer 86 and cause it to lose its insulating characteristics and short out the devices being formed. Similarly, oxygen can diffuse from the oxide dielectric into the copper decreasing its electrical conductivity. Accordingly, a Ta/TaN bilayer liner is typically interposed between the oxide and the copper although in some applications a Ta layer alone suffices. The bilayer liner includes a TaN barrier layer 90 and a Ta adhesion layer 92. The TaN barrier layer 90 adheres to the oxide layer 86 and provides a good barrier to diffusion and the Ta adhesion layer 94 wets well to both TaN on which it is formed and to the copper formed over it. It is preferred that the TaN and Ta layers 90, 92 coat the sidewalls of the via hole 88 but not coat its bottom because of the relatively high resistivity of TaN and only moderate conductivity of Ta in the current path formed in the via. However, in some applications, the TaN layer 90 is not required. Both the TaN and Ta layers 90, 92 can be deposited in the magnetron sputter reactor 10 of FIG. 1 having a target 38 with at least a sputtering surface formed of tantalum. Alternatively, atomic layer deposition (ALD), which is form of chemical vapor deposition (CVD), of the TaN layer 90 enables a very thin barrier layer. ALD is capable of growing TaN or other such compounds a monolayer at a time by alternating the supply of Ta-producing precursors and N-producing precursors.

The copper metallization is preferably deposited by electrochemical plating (ECP). However, ECP requires a plating electrode and greatly benefits from a nucleating or seed layer of copper. Accordingly, a thin copper seed layer 94 is conventionally deposited over the Ta adhesion layer 92. Again, the copper seed layer 94 can be deposited in the magnetron sputter reactor 10 of FIG. 1 having a copper target 38. It is desired that the copper seed layer 92 continuously coat the sidewall of the via hole 88 with a sufficient thickness to provide an electrode and a good conduction path for the ECP process as well as well as to uniformly nucleate the ECP copper. As will be discussed later, the copper continuity has become a major issue. It is understood that the copper may be alloyed with less than 10 wt % of alloying elements such as aluminum or magnesium although other dopants are possible.

Thereafter, ECP fills copper into the remaining portion of the via hole 88 and chemical mechanical polishing (CMP) removes whatever copper remains on top of the structure outside of the via hole 88. Most copper metallization utilizes a dual-damascene structure in which the upper-level dielectric layer 86 is etched to form a vertically differentiated structure having many vertically extending via holes 88 formed in its lower half and having horizontally extending trenches formed in its upper half connecting selected ones of the via holes 88 so as to provide horizontal interconnects as well as horizontal interconnects and horizontally extending contacts for yet further metallization levels or for bonding pads in the uppermost level. The liner bilayer 90, 92 and copper seed layer 94 are generally formed within both the vias and the trenches in a single set of steps and a single ECP step deposits the copper for the vertical vias and the horizontal interconnects in the trenches. The conductive feature 82 in the lower-level dielectric layer 84 may be formed in such a trench in the lower dielectric layer 84.

Magnetron sputtering has been successfully applied to depositing the Ta/TaN liner barrier and the copper seed layer in current generations of integrated circuits. Sidewall coverage is improved by producing a high fraction of ionized sputter particles and applying significant RF bias to the wafer pedestal 30 of FIG. 1, which in the presence of a plasma and capacitive coupling 36 of the RF power supply 34 produces a negative DC self bias. The negative voltage attract the positively charged sputter ions deep within the via hole 88. However, future generations of integrated circuits will present increasing difficulty as the width of the via hole 86 shrinks below current widths at the 90 nm node toward much smaller widths at the 32 nm node (via widths of 50 nm are forecast for the metal-1 level at the 32 nm node) while the thickness of the dielectric layer 86 remains close to 1 μm. Several problems arise from the increasing aspect ratio of the holes. The three liner layers 90, 92, 94 all need to have sufficient thickness on the via sidewalls to perform their functions, for example, a minimum thickness of 2 or 3 nm, even on the bottom portion of the sidewall. The total thickness of the liner layers begins to fill via hole 88.

Copper sputtering of the copper seed layer 94 is becoming increasingly difficult since it tends to form overhangs 96 at the top of the via hole 88. The overhangs 96 effectively increase the aspect ratio of the via hole 88 making copper sidewall coverage by sputter deposition even more difficult. Even if the overhangs 96 do not close the via hole 88, the restricted aperture at the throat to the via hole 88 may impede electrolyte flow during the ECP. The span of the overhangs 96 can be reduced if the thickness of the seed layer 94 is reduced. However, sidewall coverage is almost always less than unity compared to blanket deposition on a flat planar field region 98 on top of the surface of the Ta layer 92 so that a thinner seed layer 94 may result in the seed copper diffusing into globules 100 leaving sidewall voids 102 between the globules 100. There is some diffusion of the copper up and down the sidewall, but it is insufficient with tantalum wetting layers. The sidewalls voids 102 expose the underlying tantalum, and the exposed portions of the tantalum layer 92 are likely to oxidize to tantalum oxide when the wafer is being transferred to the electroplating apparatus. The oxidization causes two major problems. Copper does not adhere well to tantalum oxide and does not readily flow over it. Even if the copper fill bridges the sidewall voids 102 over the oxide, it may separate from the oxide during extending usage, resulting in a reliability problem. Both oxidation and copper agglomeration degrade copper gap fill. If the sidewall voids 102 are large enough and circumferentially interconnected, they may interrupt the current path for electroplating. Although the tantalum layer 92 is somewhat conducting, if it is oxidized, it is effectively an insulator blocking the electroplating current to its exposed surface as well as to other lower portions of the via hole 88. That is, the oxidized tantalum-based barrier presents a significant problem for electroplating copper and voids are commonly observed in the resultant ECP copper, whether directly from the overhangs 96 or from the discontinuous seed layer 94 at the lower two-thirds or half of the via hole 88.

A known method of reducing the overhangs 96 strongly biases the wafer during the sputter deposition or in a separate argon sputter etching step to create a high negative DC self-bias on the wafer. The bias accelerates the ions to high energy towards the wafer. The resultant high flux of energetic ions to the wafer, whether argon or sputter ions, preferentially etches the exposed corners. However, the field area on top of the dielectric layer 86 is also etched resulting in a reduction of the copper thickness in the field area. A relatively thick copper layer in this region is desired to supply electroplating current from the edge of the wafer to its center. Further, strong wafer biasing is discouraged for advanced devices because of the possible damage to very thin layers from energetic ions.

Tantalum and copper, like most metals, typically form as polycrystalline materials. The polycrystalline morphology of the tantalum layer 92 and that of the copper seed layer 94 cause several potential problems. The tantalum grain boundaries provide a ready path for the diffusion of copper so that the TaN layer 90 alone serves as the barrier. Thermal cycling of the integrated circuit during use causes differential thermal expansion, which is likely to fracture the tantalum layer 92 along its grain boundaries, and the fracture propagates through the TaN barrier layer 90, thereby introducing a reliability problem.

Ruthenium has been suggested to replace both the Ta adhesion layer 92 and the copper seed layer 94. Ruthenium does not readily oxidize and, when it does, it forms conductive ruthenium oxide. Ruthenium adheres to TaN and to copper, and it can possibly serve as both an electroplating electrode and a seed layer. However, ruthenium technology has been difficult to implement. Most attempts involve chemical vapor deposition, which is slow and chemical precursors are not readily available. Sputtering of ruthenium has been suggested and appears viable for the near future. Pure ruthenium forms as a polycrystalline metal although its crystallites are relatively small, apparently below 5 nm in size. However, ruthenium films tend to be brittle and to fracture in fabrication or use. Accordingly, the reliability and diffusion problems discussed previously for polycrystalline tantalum will likely also need to be addressed for ruthenium, for the 32 nm node and especially the 22 nm node. Even if ruthenium is provided as an additional layer on top of the oxidizable tantalum layer 92, its thickness must be minimized in view of the large number of layers already needed in the via hole 88. As a result, a thin ruthenium layer does not of itself provide a complete solution.

Accordingly, a better barrier structure is desired and it further desired that it be formed by sputtering.

### SUMMARY OF THE INVENTION

One aspect of the invention includes a liner structure for copper metallization formed in via hole dielectric, such as an oxide. The liner structure includes a barrier layer such as tantalum nitride deposited on the dielectric. A non-oxidizable refractory noble alloy layer or a refractory noble metal layer that is conducting when oxidized is deposited over the barrier layer. The refractory noble alloy may be an alloy of ruthenium and tantalum.

Another aspect of the invention includes the refractory noble alloy, such as ruthenium tantalum deposited over the dielectric with the benefit of a nitride of titanium nitride or other material other than a nitride of the refractory noble alloy.

Additionally, a nitride of the refractory noble alloy, such as RuTaN, is deposited over the dielectric and the refractory noble alloy is deposited thereover.

A further aspect of the invention includes a refractory noble alloy which is an alloy of ruthenium and tantalum, for example, having an atomic alloying ratio of between 5:95 and 95:5. Other Group VIIIB metals in the platinum group except iron may be substituted for the ruthenium. Other Group IVB, VB, and VIB metals may be substituted for the tantalum. A copper seed layer may be deposited over refractory noble metal for electroplating of copper thereover. However, the refractory noble alloy may itself act as the seed and electroplating layer.

The refractory noble alloy layer may be formed to be amorphous and with substantially no grain boundaries to act as an effective barrier. Alloys of ruthenium and tantalum having atomic alloying fractions between about 35:65 and 65:35 tend to form with an amorphous crystallographic structure under the proper deposition conditions, for example, high ionization fraction produced by high target power or small strong magnetrons. Other amorphous alloys may be used having metal-level electrical conductivity and most crystallites, if any, smaller than 1 nm.

The refractory noble alloy may be deposited by magnetron sputtering or by other method such as chemical vapor deposition.

In a further aspect of the invention, a RuTaN barrier may be deposited on the dielectric layer by reactive sputtering or by chemical vapor deposition, such as atomic layer deposition.

The invention also includes sputtering of the refractory noble alloy layer as a barrier layer and the general sputtering of an alloy of ruthenium and tantalum. The invention also includes a sputtering target having a sputtering surface comprising an alloy of ruthenium and tantalum.

Another aspect of the invention uses the refractory noble alloy layer, especially an alloy of ruthenium and tantalum as the barrier layer adjacent the dielectric. It can be used with a copper seed layer or act itself as the seed layer for copper electroplating.

Yet a further aspect of the invention includes alloying the RuTa or related barrier and adhesion layers with aluminum. When annealed, the resultant aluminum oxide acts as an interfacial barrier to moisture and other diffusing particles particularly from porous low-k dielectrics. Similar aluminum doping of ruthenium also creates an effective interfacial barrier.

One more aspect of the invention includes a contact liner structure for copper contact metallization over a silicon or silicide layer in which RuTa contact hole liners of different alloying fractions also coat the hole bottom with the respective alloying fractions selected to produce a work function better suited to the doping type of the underlying silicon layer.

A noble copper alloy seed layer may be formed of copper and one the Group VIIIB elements except iron. Ruthenium copper is the preferred noble copper alloy. The alloying percentages may be freely chosen, but small copper content below 25 at % is preferred ranging down to 1 at % or even 0.01 at %. The noble copper alloy seed layer may serve as an electroplating electrode, especially for copper.

### BRIEF DESCRIPTION OF THE DRAWINGS

FIG. 1 is a schematic cross-sectional view of a conventional magnetron sputter reactor.

FIG. 2 is a cross-sectional view of a conventional copper/tantalum via structure.

FIG. 3 is a cross-sectional view of via liner structure of one embodiment of the invention including a refractory noble alloy layer.

FIG. 4 is a cross-sectional view of a via liner structure of second embodiment of the invention including both a refractory noble alloy layer and a nitride of it, such as RuTa/RuTaN.

FIG. 5 is a cross-sectional view of a sputter target used in sputter depositing RuTa.

FIG. 6 through 9 are flow diagrams of four embodiments of a process for forming the RuTa/RuTaN structure of FIG. 4.

FIG. 10 is a cross-sectional view of a via liner structure of a third embodiment of the invention including a simple metal nitride barrier and a metal alloy adhesion layer.

FIGS. 11 and 12 are cross-sectional views of a via liner structures of a fourth and fifth embodiment of the invention including an aluminum ternary alloy barrier or adhesion layer.

FIGS. 13, 14, and 15 are cross-sectional views of three embodiments of contact liner structure using differential compositions of the near-noble refractory metal alloy for the two illustrated doped contacts of opposite conductivity type.

FIG. 16 is a cross-sectional view of a single-layer liner structure of another embodiment of the invention including the refractory noble alloy layer.

FIG. 17 is a cross-sectional view showing the completed metallization of FIG. 16.

FIG. 18 is a cross-sectional view of a via liner structure of yet another embodiment of the invention including a copper noble alloy layer.

### DETAILED DESCRIPTION OF THE PREFERRED EMBODIMENTS

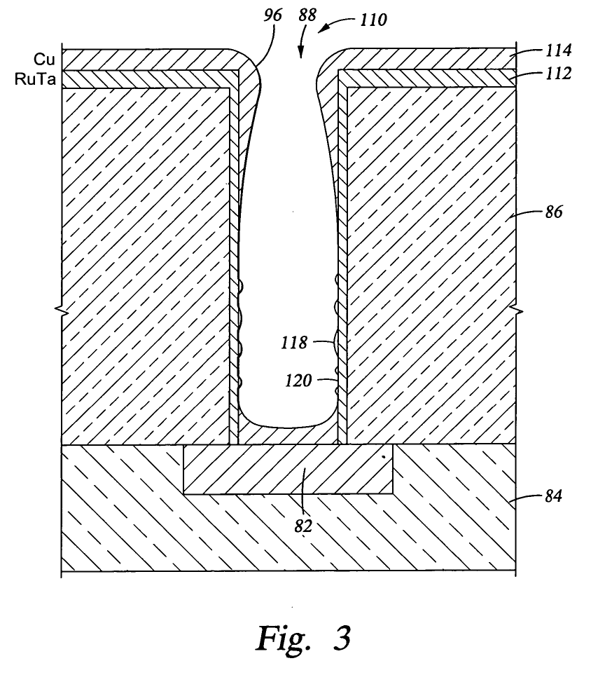

A first embodiment of a novel copper interconnect liner structure 110 is illustrated in the cross-sectional view of FIG. 3. A barrier layer 112 of an alloy of ruthenium and tantalum is deposited directly over the upper-level dielectric layer 86 and onto the sidewalls of the via hole 88. The RuTa alloy is one type of a larger class of refractory noble alloys to be discussed later. A refractory noble alloy is a metal so it is electrically conductive and can be deposited by magnetron sputtering using a target of the desired alloy composition. A copper seed layer 114 is deposited over the RuTa barrier layer 112 to serve as a plating electrode and as a seed for the copper filled into the remaining portion of the via hole 88 by electrochemical plating (ECP). The excess copper deposited above the top of the via hole 88 is thereafter removed by chemical mechanical polishing (CMP). Although Sun et al. have suggested in U.S. Patent Application Publication 2006/0063375-A1 that a RuTa layer can serve as a seed and plating layer, superior results are achieved with a separate copper seed layer on top of the RuTa barrier.

This structure provides several advantages. The ruthenium content may be sufficiently high that the RuTa alloy does not readily oxidize or at least tends to remain conductive when oxidized because of the conductivity of RuO. As a result, the RuTa barrier layer 112 or other conductive barrier layer underlying the copper seed layer 114 can both act in its exposed portions as an electroplating electrode and further conduct the electroplating current to lower portions of the via hole 88.

The RuTa alloy may form in different crystalline morphologies. In many circumstances, the RuTa alloy forms as a polycrystalline material, which for many aspects of the invention still offers many advantages. However, in one further aspect of the invention, it is possible to sputter deposit a RuTa alloy to form an electrically conductive amorphous metal, also called a glassy metal. That is, the RuTa barrier layer 112 contains substantially no crystallites, at least on the scale of greater than 1 or 2 nm readily observable by electron microscopy, and thus the RuTa barrier layer 112 contains no effective grain boundaries. An amorphous noble metal alloy has its own further advantages. The substantial lack of grain boundaries means that virtually no diffusion occurs through the amorphous metal alloy layer. The RuTa alloy also adheres well to oxide. As a result of these two effects, no TaN barrier layer may be required for an amorphous noble metal alloy layer. Glassy RuTa alloys, like most glassy metals, do not readily oxidize. The amorphous morphology of the RuTa barrier layer 112 also reduces or eliminates many of the failure mechanisms involving grain boundaries. The amorphous RuTa is somewhat plastic under stress and does not concentrate stress at the grain boundaries. Glassy metals have been widely used in the past, for example, as refractory coatings plasma sprayed onto jet engine turbines. Their use in the semiconductor industry appears to be new.

Because the electrical conductivity of amorphous 50:50 RuTa approximates that of β-phase tantalum, it is not necessary to remove the barrier layer from the bottom of the via hole 60. Barrier resistivity decreases with increasing Ru/Ta fraction. However, the bottom may optionally be removed.

However, polycrystalline RuTa also offers many advantages over the prior art.

It has been observed that if a RuTa adhesion layer is formed over either Ta or TaN, the copper seed layer sputter deposited over the RuTa shows a much stronger <111>crystallographic texturing than over more conventional Ta adhesion layers.

Increased ionization fractions of the RuTa sputter atoms in the presence of strong wafer biasing increases the tendency of given refractory noble composition to form in the amorphous state. The ionization fraction is increased by high target power, a small and strong magnetron. Increasing the power density and improving magnetic uniformity the LDR magnetron, described by Gung et al. in U.S. Pat. No. 7,018,515 changes the crystalline structure of the deposited film from polycrystalline to amorphous. The sputtering may be performed in various types of sputtering reactors. One type is the EnCoRe II Ta(N) chamber available from Applied Materials, Inc. of Santa Clara, Calif. and described by Gung et al. in U.S. patent application Ser. No. 10/950,349, filed Sep. 23, 2004 and published as U.S. Pat. No. 2005/0263389-A1, and in U.S. patent application Ser. No. 11/119,350, filed Apr. 29, 2005. All three applications are incorporated herein by reference.

The refractory noble alloys such as RuTa, whether polycrystalline or amorphous, present several advantages. Refractory ruthenium alloys, whether amorphous or polycrystalline, exhibit less stress than pure ruthenium, thus increasing the long and short time reliability. Copper adheres well to ruthenium, tantalum, or RuTa, allowing the copper seed layer 114 to be sputter deposited directly over the RuTa barrier layer 112 if desired. As discussed previously, RuTa with a high Ru content, whether polycrystalline or amorphous, does not readily oxidize and, when it does, it retains a relatively high electrical conductivity. The reduced oxidation provides more reliable wetting and bonding to the copper. The high wetting of copper to ruthenium and its alloys produces the advantage that copper tends not to agglomerate on the RuTa so that a thinner copper seed may be deposited while still remaining continuous on the via sidewall. The higher tantalum percentages are disadvantageous because of the tendency of tantalum to oxidize. However, if the oxidation problem is accounted for by other means, such as guaranteeing a continuous copper seed layer, even the low ruthenium content has been observed to promote copper hole filling, presumably because of the increased wetting promotes copper diffusion on the via sidewall. Generally, hole filling improves with increasing ruthenium fraction, all the way to 100% ruthenium, which however has its own disadvantages. Furthermore, the reduced oxidation and conductivity of ruthenium oxide allows the RuTa alloy layer to provide dependable conductive paths for the plating current if the copper is interrupted. As a result, the copper coverage need not be complete. A copper matrix pattern with holes therethrough is satisfactory as long as the matrix has sufficient density to nucleate the ECP copper. Even if the copper agglomerates in deposition or further processing, the exposed non-oxidized or at least conductive RuTa layer provides both vertical and horizontal conduction paths for the electroplating current.

Copper overhangs 96 may still form but, because of the thinner seed layer 114, they are less likely to significantly close the throat of the via hole 88. Further, the increased sidewall diffusion of copper over a ruthenium-based layer may draw the overhang material into the via hole, thus decreasing the extent of the overhang. Accordingly, the more aggressive means to prevent overhangs or to etch them can be avoided. Even if the thin copper seed layer 114 diffuses to form agglomerations 118 with sidewall voids 120 exposing the Ru-based layer 112, the sidewall voids 120 expose a generally non-oxidizable or at least conductive barrier, such as RuTa. However, agglomerations 118 and voids 120 are reduced because of the better wetting of the Ru-based layer 112. The barrier provides an electroplating electrode as well as an electroplating lower portions of the via hole 88. The sputter etching of copper allows a significantly thicker copper layer in the field region, thus promoting the flow of electroplating current from the edges of the wafer.

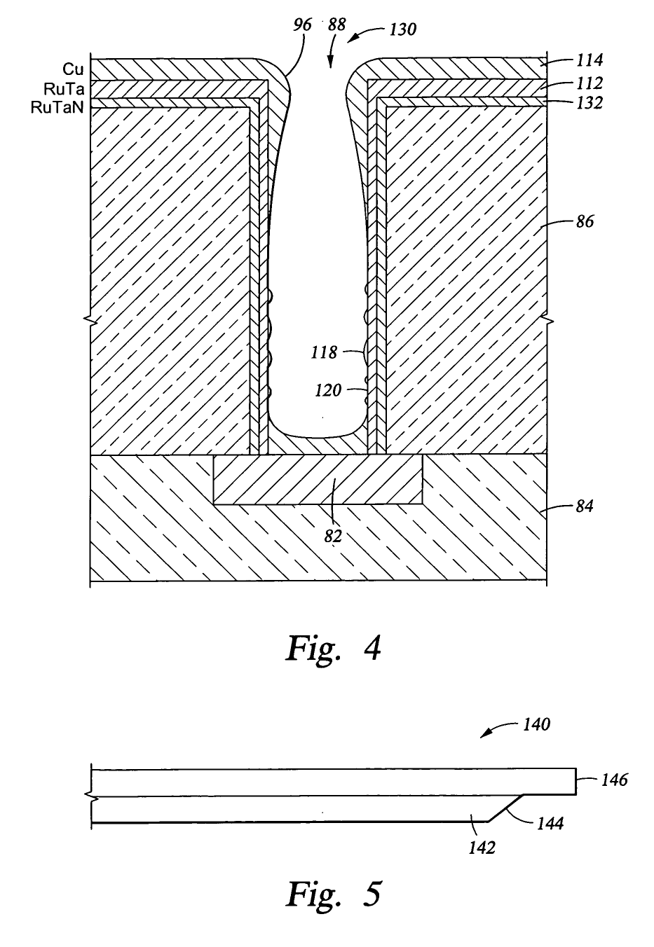

Reliability is improved in a via liner structure 130 illustrated in the cross-sectional view of FIG. 4. A RuTaN barrier layer 132 is deposited onto the upper dielectric layer 86 including the sidewalls of the via hole 88. The RuTaN provides better adhesion to the oxide dielectric layer 86 and more effectively blocks the migration of copper and oxygen. The nitrogen fraction in RuTaN may be in the range of 0.01 to 25 at %. The RuTa barrier layer 112 is then deposited over the RuTaN barrier layer 132. Both the RuTa and RuTaN barrier layers 112, 132 may be sputter deposited in the same sputter reactor by the selective supply of nitrogen gas during the nitride deposition.

A series of bending adhesion tests were performed for planar structures various metals deposited on a silica substrate by sputtering. The adhesion strength G_{c} was measured by a 4-point bending tests. The results are summarized in TABLE 1.

TABLE 1

| | G_{c} (J/m²) |
|---|---|
| SiO₂/PVD Ru | <3 |
| SiO₂/PVD RuTa | 10 |
| SiO₂/PVD Ta | 12 |
| SiO₂/PVD RuTaN | 24 |

The data demonstrate the brittleness of pure ruthenium and that a RuTa alloy with 90 at % Ru is almost as rugged as pure tantalum. Importantly, the RuTaN layer is twice as strong as either Ta or RuTa. Similar tests determined the adhesion of the copper seed and fill over the three metals. All showed a bending strength in excess of 20 J/m².

In verification tests, several such liner structures have been sputter deposited. The RuTa alloy may be co-sputtered from a mosaic target composed of tantalum areas and ruthenium areas or from separate Ru and Ta sputter sources with the alloy fraction controllable by the relative powers applied to the Ru and Ta targets. Ion beam sputtering or pulsed laser depostion (PLD) also facilitate sputtering from mixed targets. However, for reduced cost and ease of operation, a uniform RuTa target of a predetermined alloying fraction is desired, but ruthenium and tantalum are immiscible in each other. Nonetheless, a substantially uniform RuTa target 140 illustrated in partial cross-section in FIG. 5 may be formed by sintering together a mixture of pure ruthenium powder and pure tantalum powder in a proportion corresponding to the desired RuTa alloying percentage. The mixed powders and a sintering agent are filled into a sintering mold. The mold is processed at high temperature and optionally at high pressure to form a free-standing target disk 142 of RuTa with edge bevels 144 shaped in correspondence to the shield 36 with a plasma dark space between them. The sintering process is well known in the target industry. Diffusion bonding at elevated pressure and temperature and including a glass metal bonding layer may be used to bond the resultant target disk 142 to a backing plate 146, for example, composed of brass, but other forms of target bonding are known. Part of the backing plate 146 is left uncovered to serve as a flange for mounting the target 140 on the sputtering chamber.

The alloying percentages for a RuTa barrier or similar barrier may vary between 5:95 and 95:5 in atomic percentages for ruthenium and tantalum respectively. It is believed that the amorphicity is promoted by near equal atomic percentages, that is, a 50:50 RuTa alloy. But even 5 at % of ruthenium is sometimes advantageous. However, ruthenium is expensive and brittle and so subject to fraction. On the other hand, tantalum oxidizes so that the extreme percentages are not preferred. A ruthenium fraction of 80 at % or even 70 at % has been observed in some experiments to form as small crystallites though careful process tuning of sputtering ionization fraction and wafer biasing may allow 80:20 RuTa be made to deposit in an amorphous phase. However, 57 at % of ruthenium has been observed to form as a glassy film under the proper conditions. Accordingly, 20:80 and 80:20 RuTa alloys may represent desired alloying limits for an amorphous layer and the same range promises good results with polycrystalline RuTa with good oxidation resistance. However, higher ruthenium fractions than 80 at % may be desired to prevent any oxidation.

The choice of barrier material and in particular the ruthenium fraction affect the gap filling of the ECP copper. A series of structures were formed with metal or metal alloy barrier layers of 10 nm thickness formed in 100 nm vias with an aspect ratio of 5 and 70 nm trenches with an aspect ratio of 3. Various thickness of the seed layer was varied between 15 and 80 nm. The results are shown in TABLE 2 with an O indicating insufficient gap fill and an X indicating satisfactory gap fill.

TABLE 2

| Cu Seed | | | | | | | | |
|---|---|---|---|---|---|---|---|---|
| Thickness | Ta | | Ta_{0.5}Ru_{0.5} | | Ta_{0.2}Ru_{0.8} | | Ta_{0.05}Ru_{0.95} | |
| (nm) | via | trench | via | trench | via | trench | via | trench |
| 150 | ◯ | X | ◯ | X | X | X | X | X |
| 300 | ◯ | X | X | X | X | X | X | X |
| 450 | ◯ | X | X | X | X | X | X | X |
| 600 | ◯ | X | X | X | X | X | X | X |
| 800 | ◯ | X | X | X | X | X | X | X |

The data show that the TaRu alloy barrier produces superior gap fill over a Ta barrier. However, as discussed above, a Ru fraction of even 0.5 resulted in poor gap fill for the thinnest copper seed layer. However, a pure Ru barrier has been demonstrated to be too brittle. Accordingly, the data shows that a preferred Ru:Ta alloying range extends from greater than 50:50 to 95:5 and more preferably from 80:20 to 95:5, all expressed in atomic percent. Nonetheless, a ruthenium fraction of from 1 to 99 at % in RuTa provides some advantages of the invention.

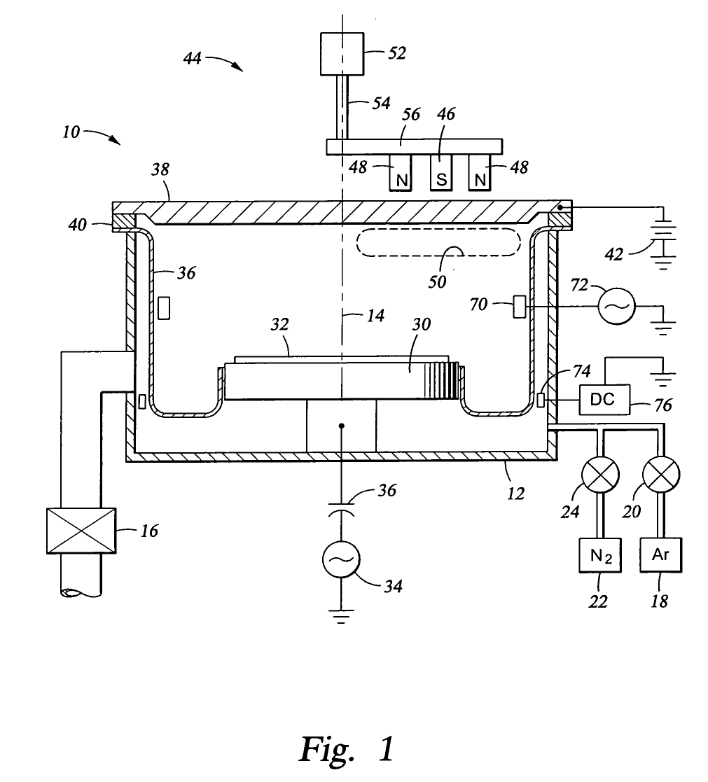

An integrated process for forming the inter-level metallization is summarized in the flow chart of FIG. 1. An optional preclean step 150 cleans residue and oxidation from the wafer, which may have been stored at atmospheric pressure in the clean room ambient. The precleaning can be performed a number of ways. A hydrogen plasma may be generated in the sputter chamber or other cleaning chamber containing the wafer or it may be generated in a remote plasma source (RPS) and then transported to the processing chamber, which has the effect of removing the hydrogen ions and relying upon hydrogen radicals for the cleaning. The cleaning may be performed as a thermal anneal in a hydrogen gas ambient. Alternatively, cleaning may be performed using an argon plasma which bombards the wafer with low-energy argon ions.

A standard nitride barrier deposition step 152 deposits a nitride barrier of RuTaN and a standard alloy barrier deposition step 154 deposits a alloy barrier of RuTa. Conveniently, both standard barrier deposition steps 152, 154 are performed in a sputter chamber having a RuTa target of the desired ruthenium fraction. Nitrogen is admitted into the chamber during the nitride barrier deposition step 152. Both barrier deposition steps 152, 154 are performed with moderate wafer biasing and high target power so that the sputter ions are attracted into the high-aspect via hole but with sufficiently low energy to reduce the amount of sputter etching of the wafer, particularly in the exposed field region. However, these conditions also favor deposition of the barrier layers at the bottom of the via hole, which degrades the contact resistance to the underlying conductive feature. Exemplary thicknesses for both steps are 2 nm in the blanket region, although lesser thicknesses and thicknesses up to about 10 nm may be effective.

A punch through step 156 removes the barrier layers at the bottom of the via hole. The punch through may be accomplished with an argon plasma or strong sustained self-sputtering of metal target ions in combination with strong wafer biasing to attract the energetic argon or metal ions to the bottom of the via hole and sputter the barrier layers there. The punch through step 156 may be performed in the RuTa sputter chamber equipped with an RF-powered inductive coil and with minimal DC power applied to the target. A exemplary sputter etch depth is 4 nm in the field region, which may remove all of the barrier in the field region but should also remove the barrier at the via bottom, which are typically deposited with less than unity coverage. However, lesser etching depths and etching depths up to 4 nm may be used depending upon the barrier thicknesses. Under the wafer strong biasing, sidewall etching at least in the upper portions of the high aspect-ratio via hole is reduced because of geometrical effects.

A RuTa flash step 158 redeposits RuTa on the field region and around the lip of the via hole to assure that the underlying dielectric is covered with barrier material, which may have been exposed in the punch through step 156. The RuTa flash deposition is performed under conditions favoring a low-energy generally isotropic deposition, for example, from Ru and Ta neutral sputter atoms, as may be achieved with reduced target power and reduced wafer biasing. The flash step 158 may be performed in the same RuTa sputter chamber. An exemplary flash thickness is 2 nm in the field region, although lesser thickness and thicknesses up to about 10 nm may be used.

In a copper seed deposition step 160, a generally conformal copper seed layer is deposited within the via hole and on the field region. An exemplary seed thickness is 20 nm, but lesser thicknesses and thicknesses up to about 100 nm may be used depending on the geometry. Sputter of the copper seed layer is preferred using a copper target if adequate sidewall coverage can be obtained. Alternatively, the seed layer may be deposited by chemical vapor deposition (CVD), by atomic layer deposition (ALD), or by an electroless process. Although in some applications, the RuTa layer may act as a seed and plating electrode, at this time, a separate copper seed layer offers advantages.

Finally, in ECP step 162, electrochemical plating is used to fill the remainder of the via hole with copper using the seed layer as both a seed and a plating electrode. The ECP step 162 also over fills the via hole and coats the top of the field region. In an unillustrated step, the excess copper is removed by chemical mechanical polishing (CMP) which levels the structure to the top of the field region. The copper hole filling may alternatively be performed using direct plating or an electroless process.

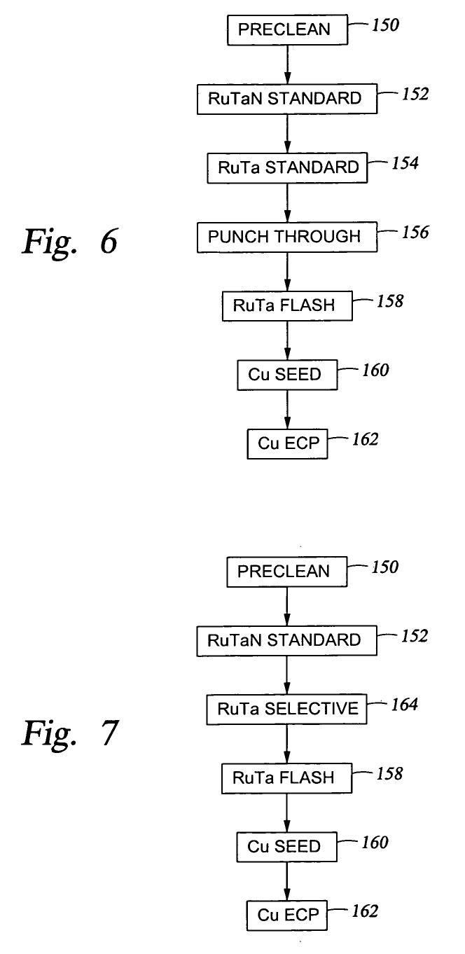

There are several variations of the basic flow diagram of FIG. 6. As illustrated in the flow diagram of FIG. 7, the punch through step 156 may be eliminated if a selective alloy barrier deposition step 164 replaces the standard alloy barrier deposition step 154. The selective deposition step 164 selectively etches the via bottom while depositing on the via sidewall. This may be accomplished with high target power producing a high ionization fraction of sputtered atoms and strong wafer biasing. Under these conditions, the via sidewalls are being coated while the via bottom and possibly the field region are being etched. An exemplary thickness for the selective RuTa sputter deposition step 164 is 2 nm in the field region although net deposition thicknesses of −2 nm to +5 nm may be used. Because the selective alloy barrier deposition step may remove at least part of the RuTaN barrier layer in the field area and does not always deposit RuTa there, the selective RuTa sputter deposition step 164 is followed by the RuTa flash deposition step 158.

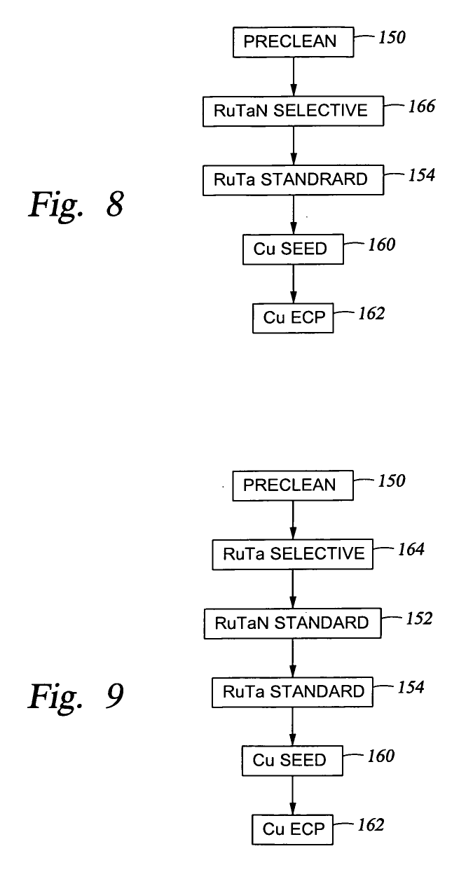

In another variation illustrated in the flow diagram of FIG. 8, both the punch through step 156 and the RuTa flash step 158 may be eliminated. In this case the standard nitride barrier step 152 is replaced by a selective nitride barrier deposition step 166 is performed under selective etch conditions which produces net etching at the via bottom and zero or net deposition in the field regions. This can be accomplished by a combination of strong wafer biasing with a substantial sputter ionization fraction but also a substantial neutral sputter deposition, the latter of which balances the ionized sputter etching in the field region but cannot reach the via bottom because of geometrical effects. The subsequent standard RuTa deposition step 152 deposits RuTa on the via bottom and on field region so no RuTa flash step 158 is required. The possible absence of a nitride barrier region in the field region should not create any problems since the field area is overlaid with dielectric or other non-metal layer in the subsequent metallization layer.

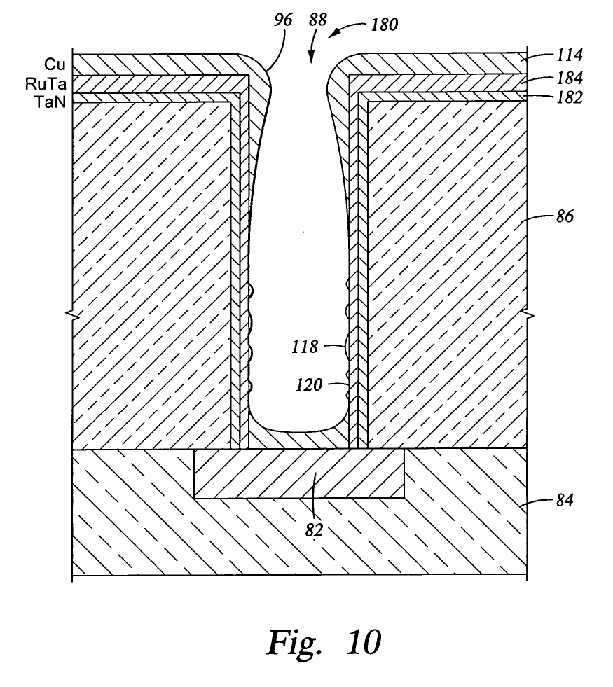

In yet another variation illustrated in the flow diagram of FIG. 9, the punch through step 156 and the flash step 158 are eliminated. However, prior to the standard nitride barrier deposition step nitriding step 152, the selective alloy barrier deposition step 164 is performed under selective etch conditions which produces net etching at the via bottom and zero or positive net deposition of RuTa in the field region. An exemplary RuTa thickness is 2 nm in the field region.

Two kinds of sputter deposition are described in the above integrated process, standard deposition and selective deposition with possible etching. A sample set of ranges of process parameters for the standard deposition of RuTa and RuTaN are summarized in TABLE 3. The standard deposition is intended to provide substantial net deposition on the field region, on the via sidewalls, and on the via bottom. The DC power is the DC power applied to the target. The bias power is the RF power applied to the pedestal. Advantageously, the bias power may be divided between an LF source operating at between 400 kHz and 13.56, preferably 13.56 MHz, and a VHF source operating at 60 MHz or above. The flows of argon and nitrogen into the chamber are listed. Additionally, 4 sccm of argon flows to the back side of the wafer as a thermal transfer gas. The ranges of parameters are sized for a 300 mm chamber.

TABLE 3

| | RuTaN | RuTa |
|---|---|---|
| DC Power (kW) | 10-40 | 10-40 |
| Bias Power (W) | 0-1000 | 0-1000 |
| Ar (sccm) | 4 | 4 |
| N₂ (sccm) | 4-100 | 0 |

In general, the target power is high but the wafer bias power is low so that sputter ions are not greatly accelerated to the wafer. A flash step would have little if any wafer biasing. The supply of nitrogen determines if RuTaN or RuTa is being sputter deposited.

A sample set of ranges of process parameters for the selective deposition and possible etching are summarized in TABLE 4.

TABLE 4

| | RuTaN | RuTa |
|---|---|---|
| DC Power (kW) | 5-40 | 5-40 |
| Bias Power (W) | 400-2000 | 400-2000 |
| Ar (sccm) | 4 | 4 |
| N₂ (sccm) | 4-100 | 0 |

The target power for selective deposition may be are somewhat lower but the bias power is substantially higher resulting in some sputter etching, particularly on via bottoms and regions.

The thickness of the RuTa layer deposited on the wafer may be freely chosen. However, a preferred thickness range is 10 to 15 nm, as measured in the field region on planar top of the dielectric, although encouraging tests have been done down to 7 nm. RuTa thicknesses are contemplated down to 1 nm but thicknesses of 5 to 15 nm are a current preferred range. Sidewall coverage under proper sputtering conditions has been observed at between 10 and 20%. The copper seed layer may have a thickness in the field region of about 30 nm although it is anticipated that this thickness can be reduced.

Ruthenium and other platinum-group metals promote gap fill in high aspect-ratio holes. However, ruthenium is expensive and its use should be minimized. A via liner structure 180 illustrated in the cross-sectional view of FIG. 10 includes a simple-metal nitride barrier layer 182 and a near-noble refractory alloy layer 184 overlying it. The copper seed layer 114 is deposited over the near-noble refractory alloy layer 184. The simple-metal nitride barrier layer 182 may include many of the refractory metal nitrides, but the presently preferred nitride is TaN although TiN and WN and alloys with TaN are of high interest. The near-noble refractory alloy layer 184 may be composed of any of the large class of alloys described elsewhere, but the presently preferred such alloy is RuTa. The difference in metal compositions precludes simple sputter deposition of the two layers. However, since a first chamber is required to deposit the TaN layer 182, the tantalum layer may be deposited by PVD from a tantalum target, or advantageously be deposited by chemical vapor deposition (CVD), or even more advantageously by atomic layer deposition (ALD), a technique well developed for TaN and capable of depositing conformal and very thin TaN layers and not using expensive and relatively undeveloped ruthenium. Other nitride compositions may be substituted. When the RuTa or other near-noble refractory alloy layer is deposited by PVD, a selective deposition may be used at least initially to remove the TaN on the via bottom.

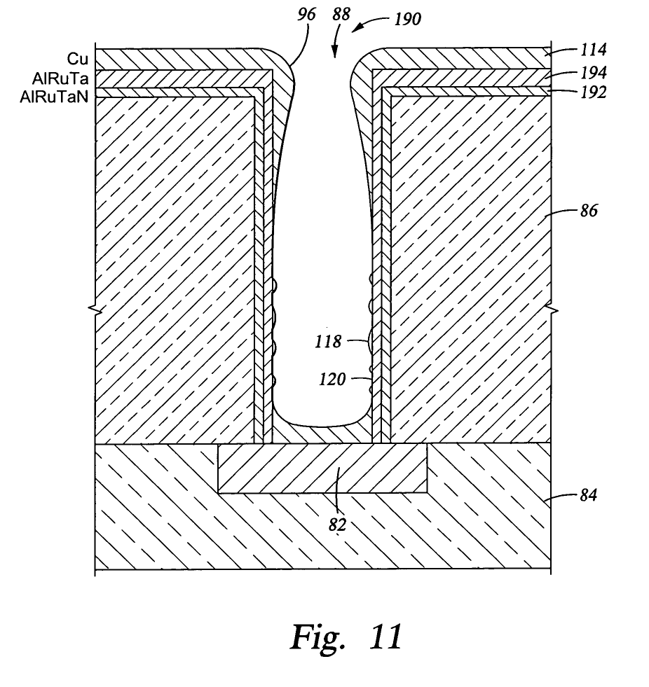

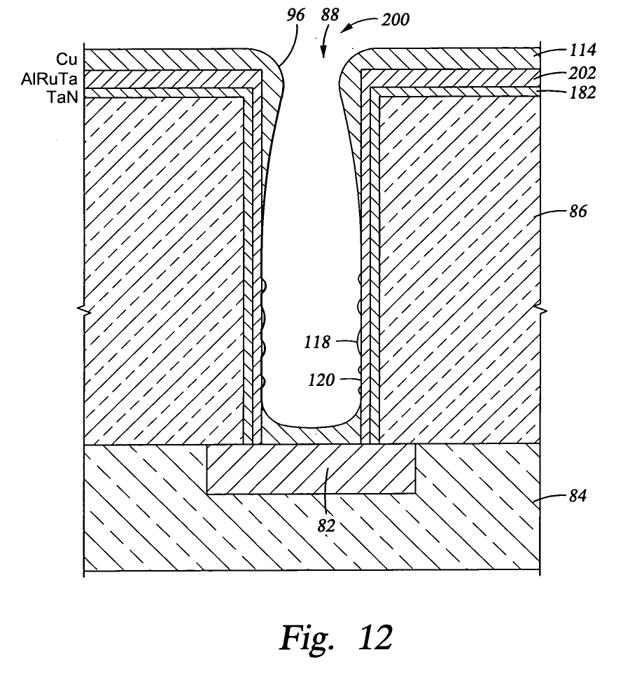

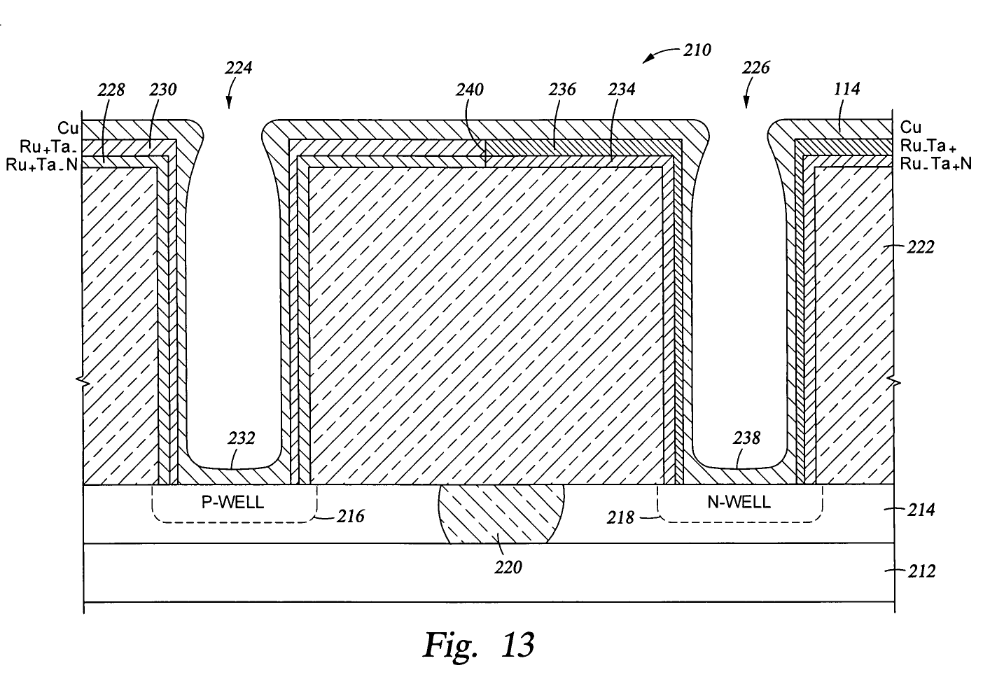

Referring to the cross-sectional view of FIG. 11, advanced circuits will most probably use a low-k dielectric material for the dielectric layer 86. The currently preferred low-k material is a porous hydrogenated silicon oxycarbide. The high porosity reduces the effective dielectric constant but is prone to trap moisture in the pores, particularly if the etch via structure is exposed to air before metallization. It is greatly desired that the via liner provide a barrier to the diffusion of molecular water from the low-k dielectric layer 86 to the copper seed layer 114. A via liner structure 190 illustrated in FIG. 11 effectively blocks the diffusion of moisture by doping the near-noble refractory alloy with aluminum. In the particularly illustrated embodiment, a nitride barrier layer 192 is composed of AlRuTaN and a ternary alloy layer 194 is composed of AlRuTa. As mentioned before, the nitrogen fraction may be in the range of 0.01 to 25 at %. Both layers 192, 194 may be sputtered from an AlRuTa target. Alternatively, a via liner structure 200, illustrated in the cross-sectional view of FIG. 12, includes the nitride barrier layer 182, for example of TaN grown by ALD interposed between a ternary alloy layer 202 of, for example, AlRuTa, and the dielectric layer 86. Aluminum is a powerful reducer for water. As a result, in either embodiment 190, 200, whatever moisture diffuses from the low-k dielectric layer 86 and strikes the aluminum-containing layers 192, 202 quickly produces a surface layer of aluminum oxide (Al₂O₃), which is quite dense and prevents any further migration of water.

The liner structures 190, 200 of FIGS. 12 and 13 may be modified so that the AlRuTa layers 194, 202 are replaced by AlRu layers with a similar modification of the AlRuTaN layer 192 to an AlRuN layer.

In all of the aluminum alloy embodiments, it is possible in some applications to eliminate the nitride barrier layer 192, 182 so that the alloy directly contacts the dielectric and provides the needed barrier function.

The initial diffusion of water out of the low-k dielectric layer may be performed as a separate anneal step after the deposition of the barrier layers 192, 194 or 182, 202, for example, at 250° C.

The previous embodiments have all been described in the context of inter-level dielectric (ILD) metallizations, that is, vertical interconnects between two layers of metallization. A contact metallization, on the other hand, provides a vertical interconnect to an underlying region of semiconducting silicon, either a crystalline active region or a polysilicon gate over a MOS channel. In the past, tungsten has been conventionally used for the contact metallization. However, it is anticipated that copper contact metallizations will be required at the 32 nm node.

A first embodiment of contact liner structure 210 for a complementary metal oxide semiconductor (CMOS) circuit is illustrated in the cross-sectional view of FIG. 13. A silicon substrate 212 includes a silicon epitaxial layer 214 into which are implanted a p-well 216 of p-type semiconductor dopants and an n-well 218 of n-type semiconductor dopants. A shallow trench isolation (STI) 220 electrically isolate the two wells 216, 218. The figure is schematic only and does not illustrate the typical complete MOS transistors in each of wells, 216, 218, specifically a PMOS transistor and an NMOS transistor respectively coupled together to form a CMOS circuit, which highly doped source and drain regions are connected through a lower-doped channel region. Typically separate source and drain contacts are silicided as, for example, NiSi, CoSi, or MoSi, for each of the transistors. Furthermore, in advanced devices a high-k gate dielectric over the silicon channel forms a gate on the channel between the source and drain in the silicon channel between them. The schematic figure also does not show the heavy doping for the source and drain regions.

A dielectric layer 222 is grown over the epitaxial silicon layer 214 including its two doped wells 216, 218. For the contact level, the dielectric layer 222 is typically composed of standard dielectric materials not selected for their low-k characteristics. An p-contact hole 224 and an n-contact hole 226 are etched through the dielectric layers to the p-well 216 and n-well 218 respectively. For the p-contact hole 224, a ruthenium-rich RuTaN layer 228 (illustrated as having a composition Ru₊Ta₋N) is deposited onto the sidewalls of the p-contact hole 224 but preferably not its bottom. A ruthenium-rich RuTa layer 230 is deposited over the ruthenium-rich RuTaN layer 228 on the sidewalls of the p-contact hole 224 and also directly over the p-well 216 to form a p-contact layer 232. For the n-contact hole 226, a ruthenium-deficient RuTaN layer 234 (illustrated as having a composition Ru₋Ta₊N) is deposed onto the sidewalls of the n-contact hole 226 but preferably not its bottom. A ruthenium-deficient RuTa layer 236 is deposited over the ruthenium-deficient RuTaN layer 234 on the sidewalls of the n-contact hole 226 and also directly over the n-well 218 to form an n-contact layer 238. The ruthernium-deficient RuTaN or RuTa layers 234, 236 can alternatively be described as tantalum-rich. A joint 240 separates the ruthenium-rich layers 228, 230 from the ruthenium-deficient layers 234, 236 in the field region generally overlying the shallow-trench isolation. The differing compositions are more concisely expressed that the ruthenium-rich Ru₊Ta₋alloy has a higher ruthenium fraction and a lower tantalum fraction than does the ruthenium-deficient Ru₋Ta₊alloy. The formation of the compositionally differentiated barrier layers includes multiple photomasking and deposition steps and possibly etching away of already formed barriers.

A copper seed layer 114 may be deposited in a single step into both the p-contact hole 224 and the n-contact hole 226. Thereafter, ECP fills copper into both the holes 224, 226 and CMP removes the copper outside the holes 224, 226 to provide respective copper contact metallizations to the p-well 216 and the n-well 218.

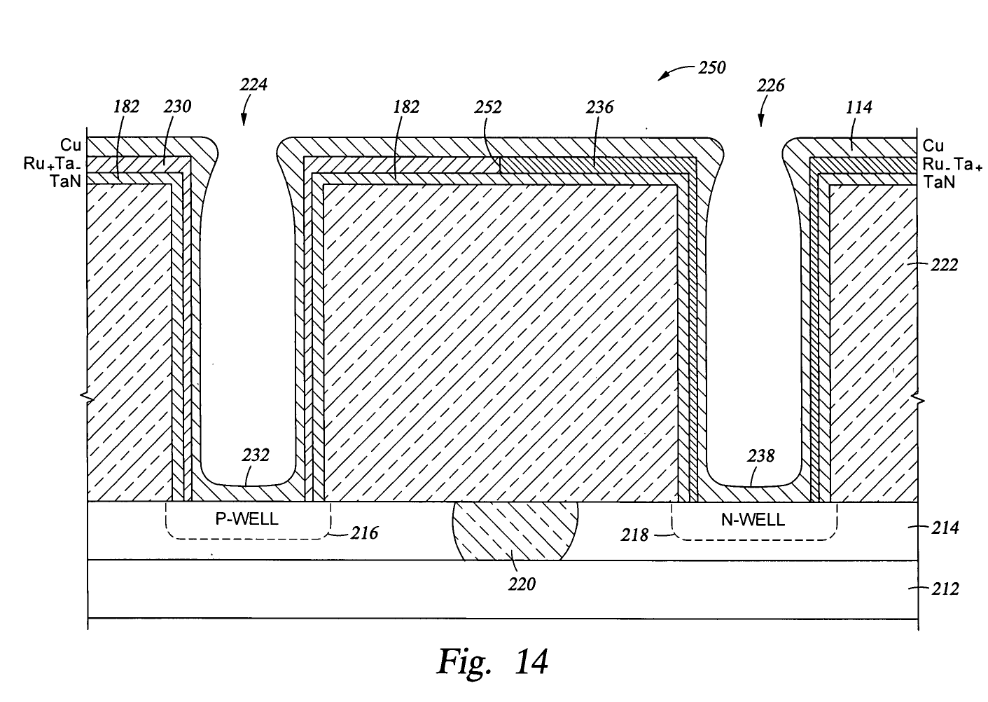

A second embodiment of a contact liner structure 250, illustrated in the cross-sectional view of FIG. 14, includes the TaN barrier layer 182 in both the contact holes 224, 226 overlain by the compositionally differentiated near-noble refractory alloy layers 230, 236. Since the TaN barrier layer 182 may be commonly deposited into both contact holes 224, 226 by ALD, a joint 252 is required only between the two alloy layers 230, 236.

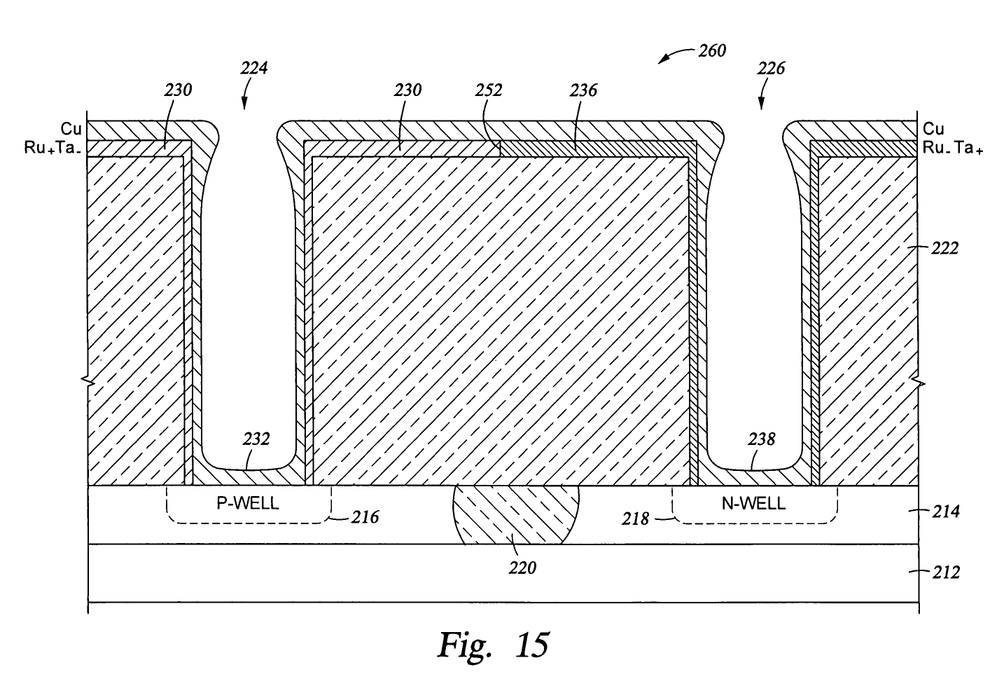

A third embodiment of a contact liner structure 260, illustrated in the cross-sectional view of FIG. 15, eliminates the TaN barrier layer 182. Instead, two near-noble refractory alloy layers 230, 236 directly contact the dielectric layer 222 as well as the two wells 216, 218. This embodiment has the advantage of not needing the removal of the TaN barrier layer at the bottom of the two contact holes 224, 226.

The compositions are graded to better match the work functions of the p-contact layer 232 and the n-contact layer 238 to the p-well 216 and the n-well 218 respectively. Generally, a tantalum-rich RuTa alloy, that is, Ru₋Ta₊, has a work function better matched to n-type silicon and a ruthenium-rich RuTa alloy, that is, Ru₊Ta₋, has a work function better match to p-type silicon.

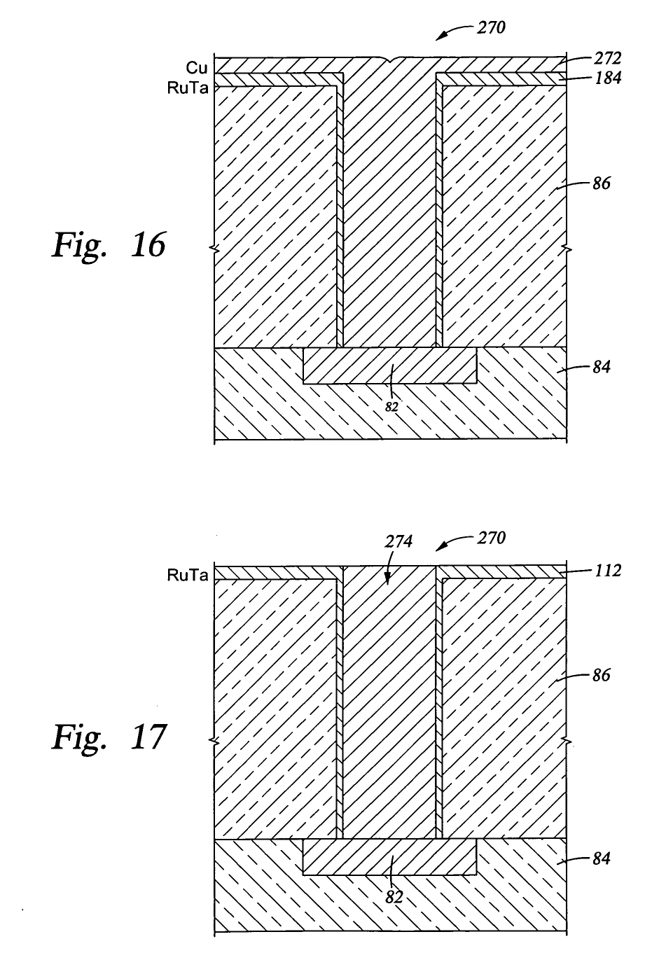

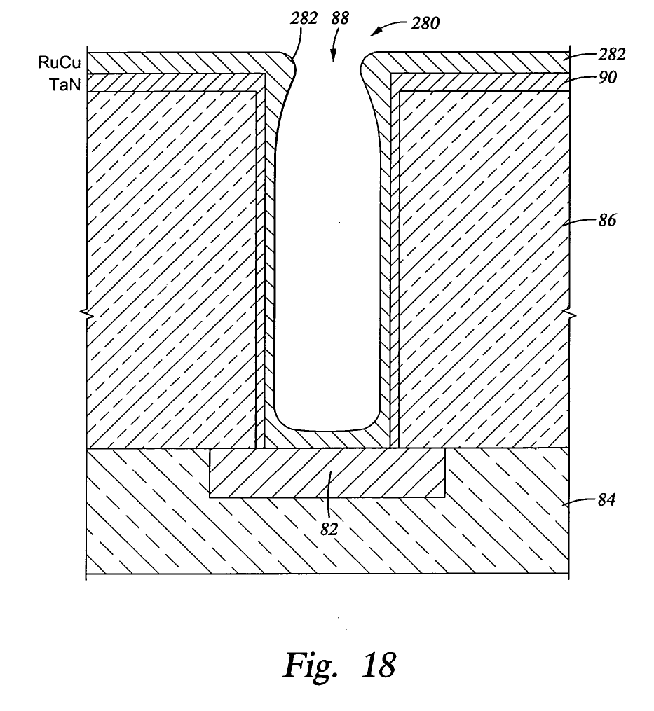

The RuTa layer, particularly when formed as an amorphous metal, allows the elimination of the copper seed layer. A copper metallization structure 270 illustrated in the cross-sectional view of FIG. 16 includes only the RuTa layer 184, which may be amorphous or polycrystalline, between the dielectric layer 86 and a copper fill 272 deposited by ECP. The RuTa layer 184 serves as a barrier layer, an adhesion layer, and an ECP electrode. The ready adhesion between copper and RuTa indicates that it will provide adequate nucleation of the ECP copper fill layer 272. Optionally, a RuTaN layer may be placed between the RuTa layer 184 and the dielectric layer 86 to promote adhesion. After the ECP, as illustrated in the cross-sectional view of FIG. 17, CMP removes the ECP copper fill 272 exposed outside of the via hole to leave a copper metallization 274 in the via hole. The CMP process may be tuned to either leave or remove the fairly hard RuTa layer 272 in the field region on top of the dielectric layer 86. It is to be appreciated that dual-damascene may result in a combination of a lower via and an upper trench connected to the via being filled by the liner and the ECP copper.

The RuTa alloy has the advantage that tantalum is widely used in the semiconductor industry and the use of ruthenium has been intensively investigated. However, other refractory noble alloys can be used to similar effect. Other near noble or platinum-group metals in Group VIIIB in the periodic table excluding iron may be substituted for all or part of the ruthenium, that is, Co, Ni, Rh, Pd, Os, Ir, and Pt, although several of these are scarce and expensive. A refractory metal chosen from Groups IVB, VB, and VIB of the periodic table, such as titanium (Ti), molybdenum (Mo), or tungsten (W), may be substituted for all or part of the tantalum. Ternary and higher-component refractory noble alloys are included within the invention and yet other elements may be included within the refractory noble alloy of the invention.

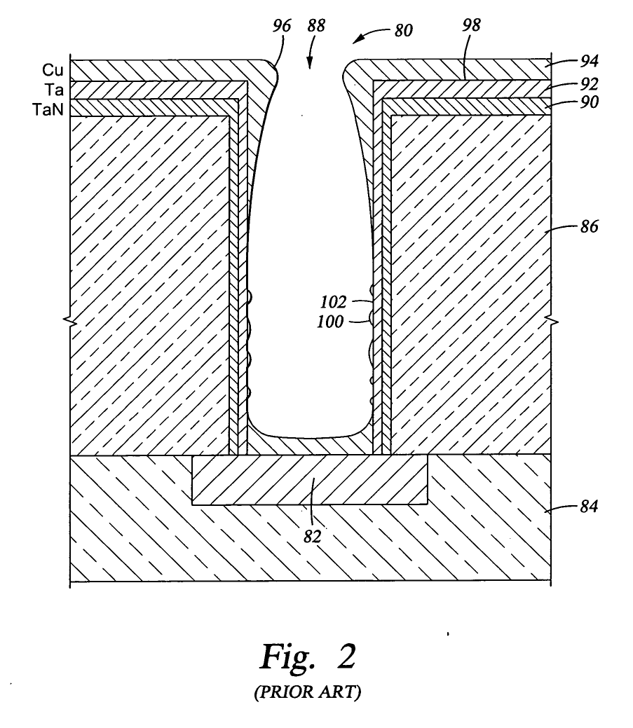

Although the RuTaN is advantageously deposited by sputtering, it may alternatively be deposited by CVD or ALD for a more conformal layer and with reduced thicknesees. A RuTaN layer may also replace the TaN layer 90 in the conventional structure of FIG. 2. The RuTaN alloy acts as a diffusion barrier but adheres well to the dielectric.

Another Ru-based layer is illustrated in the cross-sectional view of FIG. 18. A liner structure 280 is formed in the previously described via hole 88. It may include a conventional barrier layer 90, such as a conventional TaN layer deposited either by atomic layer deposition (ALD) or sputtering to be very thin, for example, 2 nm or less in thickness. Alternatively, the barrier layer 90 may be composed of RuTaN. A noble copper alloy seed layer 282 is deposited over the barrier layer 90, preferably by sputtering, which likely results in overhangs 282. The noble copper alloy seed layer 282 may be composed of a RuCu alloy or an alloy of copper with the platinum-group elements mentioned above. Besides Ru, the dopants may include iridium (Ir), osmium (Os), or palladium (Pd) or less preferably gold (Au), cobalt (Co), or rhodium (Rh). Other constituents may be included in the noble copper alloy as long as the alloy remains a conductive metal. Preferably also, the copper content is low, preferably less than 25 at %, more preferably less than 10 at % but possible lower limits are 1 at % and 0.01 at. On the other hand, a high ruthenium content of at least 50 at % provides good oxidation resistance but the invention may be extended down to ruthenium content of 1 at %. Since the RuCu alloy is conductive, there is little need to remove it from the bottom of the via hole. Ruthenium and copper are nearly immiscible with each other so that they tend to segregate during any warm temperature processing or operation. The segregation has the advantage that copper islands may form on the surface of the noble copper alloy seed layer 282 and serve as nucleation and bonding sites for an ECP copper layer filled into the via hole 88 directly over the alloy seed layer 282. No separate copper seed layer is required, but it may be included if desired. On the other hand, the segregated ruthenium acts as a further barrier and non-oxidizable or at least conducting plating electrode and plating current path.

A RuCu seed layer having between 5 and 10 at % Ru has been tested to exhibit good reflow into the via hole and no agglomeration on the sidewalls when the seed layer is annealed at 400° C.

A RuCu or related noble copper alloy sputtering target can be formed, for example, following the procedure described for the RuTa target. The RuCu alloy has the advantage of the developed technology for both of these materials

The sputter deposition of RuTa or RuCu or other ruthenium metal alloy is advantageously fast and easily implemented. However, RuTa or RuCu deposited by CVD or other method has similar advantageous material properties.

Although the illustrated via structures include few layers, other intermediary layers may be formed between the refractory noble alloy layer or the copper noble alloy layer and the dielectric and the copper fill. Although the invention is primarily directed to liners for copper metalllization, the described alloy layers may be applied to other uses and other metallizations.

The invention provides a substantially improved performance and greater simplicity over the prior art liner structures and their fabrication methods with only a slight change of the already well developed sputtering technology.

1. A method of forming a liner structure for a copper metallization, comprising:
providing a substrate having a hole formed in a dielectric layer;
a first step of forming a first barrier layer over at least sidewalls of the hole comprising an alloy of at least 5 at % of a refractory metal chosen from Groups IVB, VB, and VIB of the periodic table and at least 5 at % of a platinum-group metal chosen from Group VIIIB of the periodic table except iron; and
a second step of forming a copper seed layer over the adhesion layer which does not fill the hole.

2. The method of claim 1, further comprising a third step of forming a second barrier over at least the sidewalls comprising a nitride of the refractory metal and the platinum-group metal.

3. The method of claim 1, further comprising a third step of forming a second barrier layer between the first barrier layer and the sidewalls comprising tantalum nitride.

4. The method of claim 3, wherein the third step comprises atomic layer deposition of tantalum nitride.

5. The method of claim 1, wherein the first barrier layer contacts the dielectric layer and the copper seed layer.

6. The method of claim 1, wherein the copper seed layer comprises an alloy of copper and at least one of

7. The method of claim 1, wherein the hole is a p-contact hole overlying a p-doped semiconductor region of the substrate, the alloy comprises a first alloy, the first barrier layer forms a first contact layer at a bottom of the p-contact hole and the substrate further comprises an n-contact hole overlying an n-doped semiconductor region of the substrate, the method further comprising forming a second barrier layer over at least sidewalls of the n-contact hole, forming a n-contact layer at a bottom of n-contact hole, and comprising an alloy of at least 5 at % of a refractory metal chosen from Groups IVB, VB, and VIB of the periodic table and at least 5 at % of a platinum-group metal chosen from Group VIIIB of the periodic table except iron, wherein compositions of the first and second barrier layers are different and are chosen to correspond to doping types of the n-doped and p-doped semiconductor regions.

8. The method of claim 7, wherein the first and second barrier layers comprise tantalum and ruthenium, wherein a fraction of ruthenium is greater in the first barrier layer than in the second barrier layer and a fraction of tantalum is greater in the second barrier layer than in the first barrier layer.

9. The method of claim 1, wherein the refractory metal comprises tantalum and the platinum-group metal comprises ruthenium.

10. The method of claim 9, wherein the first and second steps are performed in a single sputter chamber having a target comprising ruthenium and tantalum.

11. The method of claim 9, wherein the barrier layer comprises greater than 50 at % and no more than 95 at % ruthenium.

12. The method of claim 11, wherein the barrier layer comprises between 80 and 95% ruthenium.

13. The method of claim 9, further comprising a subsequent step of filling the hole with copper in an electrochemical plating process.

14. A method of forming a liner structure for a copper metallization, comprising:
providing a substrate having a hole formed in a dielectric layer;
a first step of forming a first layer over at least sidewalls of the hole comprising tantalum and between 80 and 95 at % ruthenium.

15. The method of claim 14, further comprising a prior second step of forming a second layer comprising ruthenium tantalum nitride over at least the sidewalls of the hole.

16. The method of claim 15, further comprising a third step after the first step of forming a copper seed layer over the first layer which does not fill the hole.

17. The method of claim 14, wherein the first and second steps are performed in sputter chamber including a target comprising ruthenium and tantalum.

18. The method of claim 14, further comprising a subsequent step of forming a copper seed layer in the hole which does not fill the hole.

19. A metallization structure, comprising:
a dielectric layer formed over a substrate and including a hole over a conductive feature in the substrate;
a first layer comprising tantalum and between 80 and 95 at % ruthenium formed on at least sidewalls of the hole.

20. The structure of claim 19, further comprising a second layer formed between the first layer and the sidewalls of the hole comprising tantalum ruthenium nitride.

21. The structure of claim 20, further comprising a copper layer formed over the first layer within but not filling the hole.

22. The structure of claim 19, further comprising a copper layer formed over the first layer within but not filling the hole.

23. A metallization structure, comprising:
a dielectric layer formed over a substrate and including a hole over a conductive feature in the substrate;
a first layer formed on at least sidewalls of the hole and comprising an alloy of at least 5 at % of a refractory metal chosen from Groups IVB, VB, and VIB of the periodic table and aat least 5 at % of a platinum-group metal chosen from Group VIIIB of the periodic table except iron; and
a copper layer formed over the first layer within but not filling the hole.

24. The metallization structure of claim 23, wherein the alloy additionally comprises aluminum.

25. The metallization structure of claim 23, wherein the refractory metal comprises tantalum and the platinum-group metal comprises ruthenium.

26. The metallization structure of claim 25, wherein the alloy additionally comprises aluminum.

27. The metallization structure of claim 25, further comprising a second layer comprising ruthenium tantalum nitride formed between the first layer and the sidewalls of the hole.

28. The metallization structure of claim 25, wherein the first layer comprises at least 50 at % and no more than 95 at % of ruthenium.

29. The metallization structure of claim 28, wherein the first layer comprises at least 80 at % of ruthenium.
